(19) United States
(12) Patent Application Publication
(10) Pub. No.: US 2010/0238695 A1
(43) Pub. Date: Sep. 23, 2010

(54) MEMORY MODULE INCLUDING MEMORY CHIPS

(75) Inventor: Takao ONO, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 12/727,008

(22) Filed: Mar. 18, 2010

(30) Foreign Application Priority Data
Mar. 18, 2009 (JP) 2009-065519

(51) Int. Cl. G11C 5/02; G11C 7/00

(52) U.S. Cl. 365/51; 365/193

(57) ABSTRACT

To provide a module substrate, memory chips mounted on the module substrate, and data input/output wirings that are connected respectively to the memory chips and read data or write data is transmitted thereto. The number of memory chips is equal to the number of bits of read data or write data transmitted through the data input/output wirings at the same time. Because a plurality of data input/output wirings are connected to different memory chips, the load exerted upon each channel can be reduced without using memory buffers.

### BACKGROUND OF THE INVENTION

1. Field of the Invention

The present invention relates to a memory module including memory chips mounted on a module substrate.

2. Description of Related Art

Memory chips represented by DRAM (Dynamic Random Access Memory) are usually used as memory modules with the memory chips mounted on a module substrate. Memory capacity required for memory modules has been further increased in recent years, and to meet such demand, the number of memory chips mounted on a memory module is also increasing.

FIG. 9 is a schematic diagram showing a configuration of a general memory module.

According to the memory module shown in FIG. 9, 72 memory chips each of which has four data input/output terminals DQ (×4 memory chip) are mounted on a module substrate 80, and 72 data input/output wirings DQL (channels) are provided. That is, 72 bits of read data or write data can be inputted/outputted at the same time.

The memory chips MC₁ to MC₇₂ are selected by corresponding chip select signals CS0 to CS3. Specifically, 18 memory chips are assigned to each of the chip select signals CS0 to CS3. When any of the chip select signals CS0 to CS3 is activated, the 18 memory chips are selected at the same time. As described above, because each memory chip has four data input/output terminals, 72 bits (18 chips×4 I/Os) of data can be inputted/outputted at the same time.

Data input/output terminals DQ of four memory chips selected by different chip select signals (for example, memory chips MC₁, MC₁₉, MC₃₇, and MC₅₅) are connected to same data input/output wirings DQL. Because a plurality of memory chips are connected to one data input/output wiring DQL in the conventional memory module, a load of the data input/output wiring DQL in terms of a memory controller 90 is large, which prevents high speed data transfer.

To deal with the problem, when high data transfer rate is required, a memory module known as “fully buffered memory module” is utilized (see Japanese Patent Application Laid-open No. 2006-268683). According to the fully buffered memory module, a plurality of memory modules are cascade-connected. Therefore, even if the number of memory modules is increased, the load exerted upon channels is not increased.

In the fully buffered memory module, in addition to memory chips, a memory buffer called AMB (Advanced Memory Buffer) is mounted on a module substrate. The memory buffer functions to buffer addresses, data, and commands supplied from the memory controller 90 to transfer to the memory chips on the memory module.

However, when the memory buffer is mounted on the memory module, the cost is increased correspondingly as well as the size of the memory chip capable of being mounted is reduced.

### SUMMARY

In one embodiment, there is provided a memory module comprising: a module substrate; a plurality of memory chips mounted on the module substrate, each of which includes a data input/output terminal; and a plurality of data input/output wirings formed on the module substrate to which read data or write data is transmitted, each of the data input/output wirings being individually connected to an associated one of the data input/output terminal.

In another embodiment, there is provided a memory module comprising: a module substrate; a plurality of memory chips mounted on the module substrate; a plurality of data input/output wirings formed on the module substrate to which read data or write data is transmitted, each of the data input/output wirings being individually connected to an associated one of the memory chips; and a data strobe wiring formed on the module substrate to which a data strobe signal indicating a timing of inputting/outputting the read data or the write data for the memory chips is transmitted, each of the data strobe wiring being connected commonly to the memory chips.

According to the present invention, a plurality of data input/output wirings are connected to a plurality of input/output terminals or a plurality of memory chips, respectively. Therefore, the load exerted upon each channel can be reduced without using memory buffers.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a schematic diagram of a configuration of a memory module according to a first embodiment of the present invention;

FIG. 2 is a schematic diagram of a configuration of a memory module according to the second embodiment;

FIG. 3 is a schematic diagram for explaining a configuration of the memory chips used in the second embodiment;

FIG. 4 is a schematic diagram of a configuration of a memory module according to the third embodiment;

FIG. 5 is a block diagram showing data strobe signal input/output circuits provided in the memory chips shown in FIG. 1 and represents the fourth embodiment;

FIG. 6 is a block diagram showing data input/output circuits provided in the memory chips shown in FIG. 1 and represents the fifth embodiment;

FIG. 7 is a schematic diagram of a configuration of a memory module according to the sixth embodiment;

FIG. 8 is a schematic diagram of a configuration of a memory module according to the seventh embodiment; and

FIG. 9 is a schematic diagram showing a configuration of a general memory module.

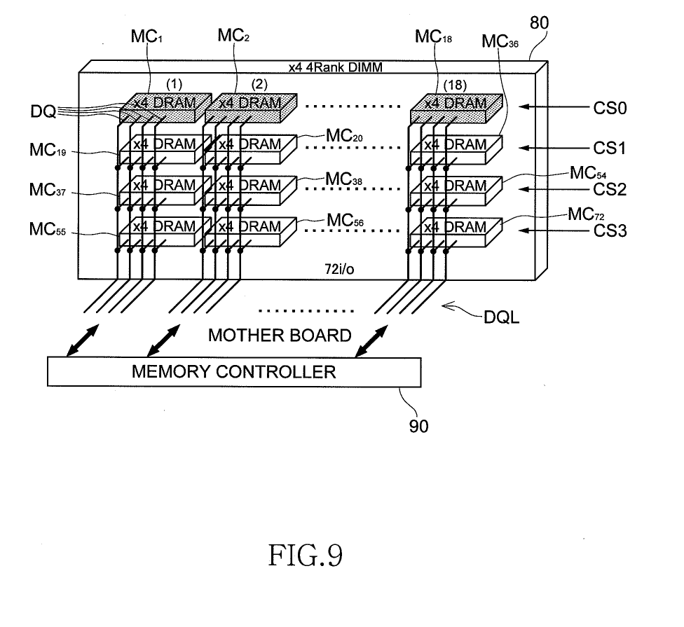

### DETAILED DESCRIPTION OF THE EMBODIMENTS

Preferred embodiments of the present invention will be explained below in detail with reference to the accompanying drawings.

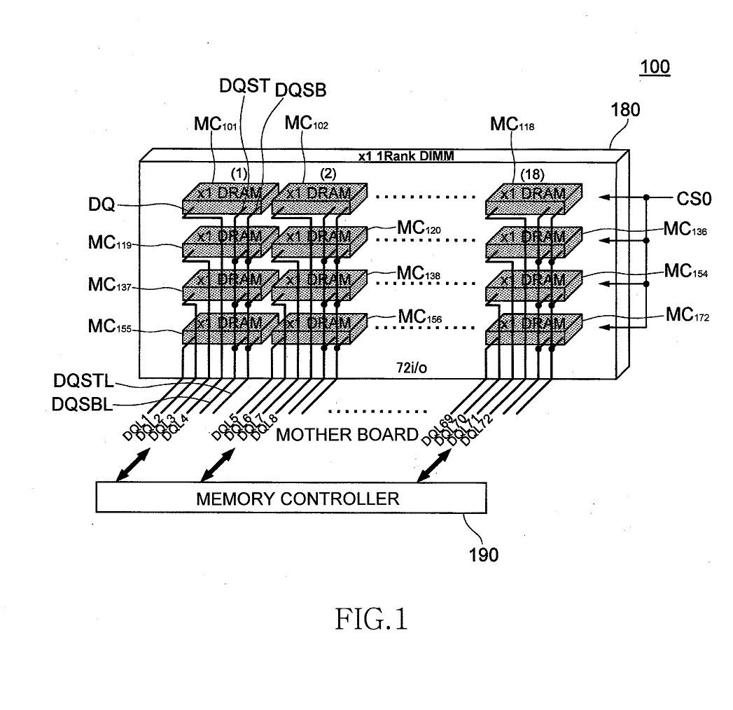

FIG. 1 is a schematic diagram of a configuration of a memory module 100 according to a first embodiment of the present invention.

As shown in FIG. 1, the memory module 100 of the first embodiment includes a module substrate (module board) 180 and 72 memory chips MC₁₀₁ to MC₁₇₂ mounted on the module substrate 180. The memory module 100 is mounted on the mother board (main board). Each of the memory chips MC₁₀₁ to MC₁₇₂ has only one data input/output terminal DQ (×1 memory chip). Each of the memory chips MC₁₀₁ to MC₁₇₂ includes a pair of data strobe terminals DQST and DQSB.

The data input/output terminals DQ provided at the respective memory chips MC₁₀₁ to MC₁₇₂ are connected respectively to data input/output wirings (channels) DQL1 to DQL72 provided on the module substrate 180. That is, the number of memory chips MC₁₀₁ to MC₁₇₂ mounted on the module substrate 180 is equal to the number of data input/output wiring DQL1 to DQL72. When 72 memory chips MC₁₀₁ to MC₁₇₂ that are ×1 memory chips are operated at the same time, 72 bits of read data or write data are inputted/outputted at the same time. Because 72 memory chips MC₁₀₁ to MC₁₇₂ are operated concurrently in the first embodiment, a single chip select signal CS0 is used.

72 memory chips MC₁₀₁ to MC₁₇₂ are divided into groups each of which consists of four memory chips. The data strobe terminals DQST and DQSB in each group are connected commonly to a same pair of data strobe wirings DQSTL and DQSBL provided on the module substrate 180. While 72 data input/output wirings are provided, only 18 (72/4) pairs of data strobe wirings are provided.

The data strobe wirings DQSTL and DQSBL are for transmitting data strobe signals indicating timings of inputting/outputting read data or write data to and from the memory chips. Specifically, during a read operation, the data strobe signal is outputted from the data strobe terminals DQST and DQSB of the memory chip and in synchronization with this, read data is outputted from the data input/output terminal DQ. During a write operation, the data strobe signal is outputted from a memory controller 190 and in synchronization with this, write data is inputted to the data input/output terminal DQ. The memory controller 190 is mounted on the mother board (main board).

In this way, according to the memory module 100 of the first embodiment, the memory chips MC₁₀₁ to MC₁₇₂ that are ×1 memory chips are used and the respective data input/output terminals DQ are connected to the corresponding data input/output wirings DQL1 to DQL72. The load of the data input/output wirings DQL1 to DQL72 in terms of the memory controller 190 is reduced. Accordingly, the quality of signals is improved and thus high speed data transfer is realized without using memory buffers.

Because 72 memory chips MC₁₀₁ to MC₁₇₂ are operated concurrently in the memory module 100 of the first embodiment, the amount of heat generated by the entire module is increased. A second embodiment of the present invention described next solves this problem.

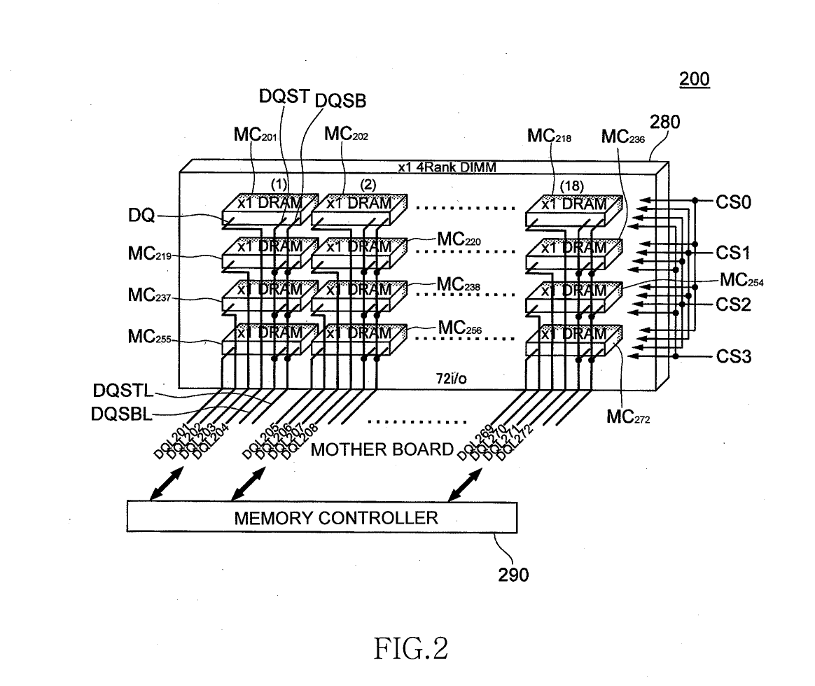

FIG. 2 is a schematic diagram of a configuration of a memory module 200 according to the second embodiment.

As shown in FIG. 2, the memory module 200 according to the second embodiment includes a module substrate 280 and 72 memory chips MC₂₀₁ to MC₂₇₂ mounted on the module substrate 280. Each of the memory chips MC₂₀₁ to MC₂₇₂ has only one data input/output terminal DQ (×1 memory chip). Each of the memory chips MC₂₀₁ to MC₂₇₂ also includes a pair of data strobe terminals DQST and DQSB. Accordingly, the basic configuration of the memory module 200 is the same as that of the memory module 100 according to the first embodiment shown in FIG. 1.

However, four chip select signals CS0 to CS3 are used in the memory module 200 according to the second embodiment. These four chip select signals CS0 to CS3 are supplied commonly to the memory chips MC₂₀₁ to MC₂₇₂. The memory module 200 is different from the memory module 100 according to the first embodiment in this aspect.

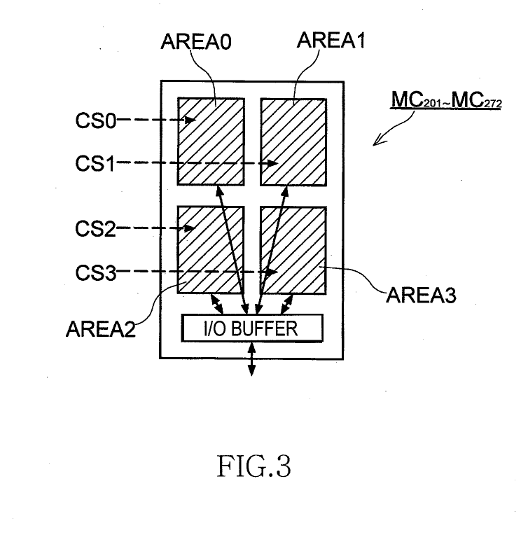

FIG. 3 is a schematic diagram for explaining a configuration of the memory chips MC₂₀₁ to MC₂₇₂ used in the second embodiment.

As shown in FIG. 3, each of the memory chips MC₂₀₁ to MC₂₇₂ used in the second embodiment is divided into four areas AREA0 to AREA3 activated based on the chip select signals CS0 to CS3. The chip select signals CS0 to CS3 are activated exclusively and two or more chip select signals cannot be activated concurrently. According to the memory chips MC₂₀₁ to MC₂₇₂, only one of the four areas AREA0 to AREA3 is thus selectively activated and only the activated area performs operations. An I/O buffer is common to the four areas AREA0 to AREA3. The selection of the areas AREA0 to AREA3 based on the chip select signals CS0 to CS3 is different from selection of banks based on bank addresses and unselected areas can be made to enter a low power consumption mode. For example, the unselected area can be made to enter a self refreshing mode or a power down mode.

Although 72 memory chips MC₂₀₁ to MC₂₇₂ are operated concurrently, only one area is activated within each memory chip. Accordingly, as only the area corresponding to one fourth of a chip is operated and the remaining area corresponding to three fourth of the chip is in a non-access state, the amount of heat generated by the entire module can be reduced considerably as compared to the first embodiment. Particularly, when the unselected areas are made to enter the low power consumption mode, the amount of heat generated by the entire module is further reduced.

While only one data input/output terminal DQ is provided on each memory chip in the first and second embodiments described above, as long as one memory chip is connected to each data input/output wiring DQL (channel), the number of data input/output terminals DQ provided on each memory chip is not limited to one. A third embodiment of the present invention described next exemplifies a case that plural data input/output terminals DQ are provided on each memory chip.

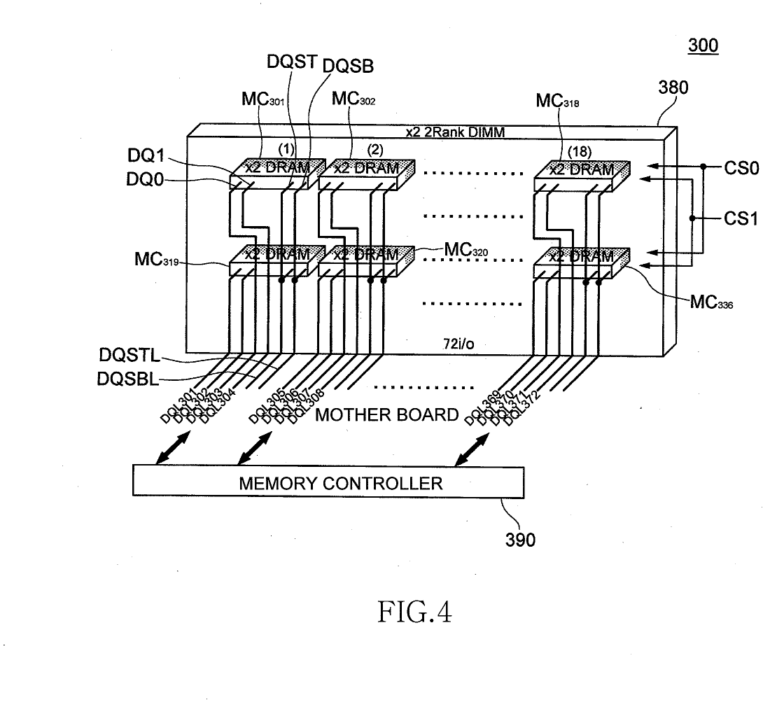

FIG. 4 is a schematic diagram of a configuration of a memory module 300 according to the third embodiment.

As shown in FIG. 4, the memory module 300 according to the third embodiment includes a module substrate 380 and 36 memory chips MC₃₀₁ to MC₃₃₆ mounted on the module substrate 380. Each of the memory chips MC₃₀₁ to MC₃₃₆ has two data input/output terminals DQ (×2 memory chip). Each of the memory chips MC₃₀₁ to MC₃₃₆ used in the third embodiment is divided into two areas activated based on chip select signals CS0 and CS1.

Data input/output terminals DQ0 and DQ1 provided on the respective memory chips MC₃₀₁ to MC₃₃₆ are connected respectively to data input/output wirings (channels) DQL1 to DQL72 on the module substrate 380. In other words, the number of memory chips MC₃₀₁ to MC₃₃₆ mounted on the module substrate 380 is half the number of data input/output wirings DQL1 to DQL72 (36). When 36 memory chips MC₃₀₁ to MC₃₃₆ that are ×2 memory chips are thus operated concurrently, 72 bits of read data or write data are inputted/outputted at the same time.

36 memory chips MC₃₀₁ to MC₃₃₆ are divided into groups each of which consists of two memory chips. The data strobe terminals DQST and DQSB in each group are connected commonly to a same pair of data strobe wirings DQSTL and DQSBL provided on the module substrate 380. While 72 data input/output wirings are provided, 18 pairs of data strobe wirings are provided.

As described above, while the memory module 300 according to the third embodiment uses the memory chips MC₃₀₁ to MC₃₃₆ that are ×2 memory chips, their data input/output terminals DQ0 and DQ1 are connected to the corresponding data input/output wirings DQL1 to DQL72, respectively. The load of the data input/output wirings DQL1 to DQL72 in terms of a memory controller 390 is thus equal to that of the first and second embodiments. Therefore, the quality of signals is improved, so that high speed data transfer is realized without using memory buffers.

As described above, according to the first to third embodiments, each data input/output wiring DQL is connected to only one memory chip and data strobe wirings DQSTL and DQSBL are connected commonly to a plurality of memory chips. In cases that a data strobe signal is supplied from the memory controller to a memory chip during the write operation and that the data strobe signal is supplied from a memory chip to the memory controller during the read operation, environments of inputting/outputting the data strobe signal are different from the ones in ordinary memory modules. Fourth and fifth embodiments of the present invention described next provide memory modules taking such environmental differences into consideration.

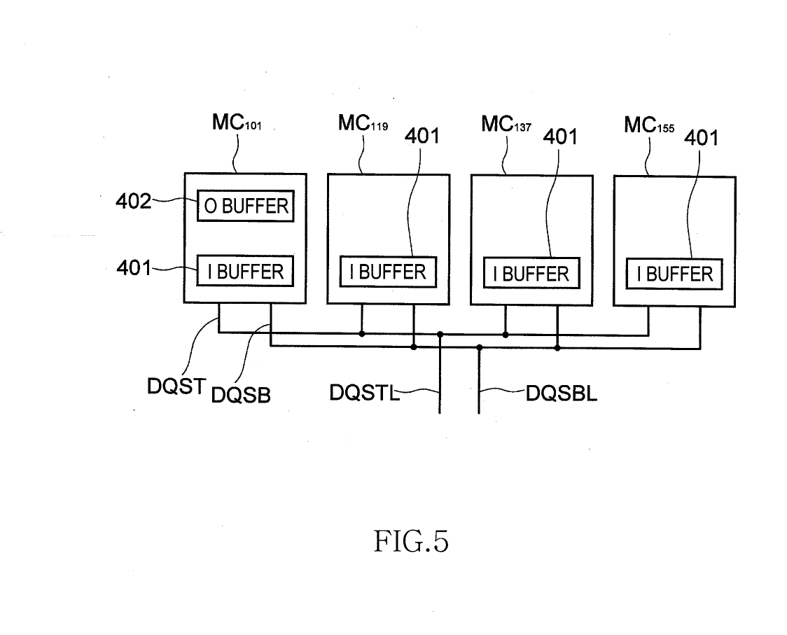

FIG. 5 is a block diagram showing data strobe signal input/output circuits provided in the memory chips MC₁₀₁, MC₁₁₉, MC₁₃₇, and MC₁₅₅ shown in FIG. 1 and represents the fourth embodiment. The memory chips MC₁₀₁, MC₁₁₉, MC₁₃₇, and MC₁₅₅ are four memory chips connected commonly to the same data strobe wirings DQSTL and DQSBL.

As shown in FIG. 5, these memory chip include data-strobe-signal input circuits (I buffers) 401. The data-strobe-signal input circuit 401 fetches data strobe signals through the data strobe terminals DQST and DQSB. The data-strobe-signal input circuits of the respective memory chips are the same configuration.

Meanwhile, a data-strobe-signal output circuit (O buffer) 402 is provided in the memory chip MC₁₀₁ but not in the memory chips MC₁₁₉, MC₁₃₇, and MC₁₅₅. That is, the memory chips MC₁₁₉, MC₁₃₇, and MC₁₅₅ do not have any function to output the data strobe signal through the respective data strobe terminals DQST and DQSB.

The reason of the above is as follows. Because write data is inputted to all memory chips MC₁₀₁ to MC₁₇₂ during the write operation, the data strobe signal must be supplied to During the read operation, however, although read data is outputted from all memory chips MC₁₀₁ to MC₁₇₂, it suffices that one of the memory chips sharing the data strobe wirings DQSTL and DQSBL outputs the data strobe signal.

By having such a circuit configuration, the load of the data strobe wirings DQSTL and DQSBL in terms of the memory controller is reduced. That is, when the data-strobe-signal output circuit 402 is connected to the data strobe terminals DQST and DQSB like the memory chip MC₁₀₁, the capacity of the data strobe terminals DQST and DQSB in terms of the data strobe wirings DQSTL and DQSBL is relatively increased. Meanwhile, when the data-strobe-signal output circuit 402 is not connected to the data strobe terminals DQST and DQSB like the memory chips MC₁₁₉, MC₁₃₇, and MC₁₅₅, the capacity of the data strobe terminals DQST and DQSB in terms of the data strobe wirings DQSTL and DQSBL is relatively reduced.

Accordingly, although plural (four in the fourth embodiment) memory chips MC₁₀₁, MC₁₁₉, MC₁₃₇, and MC₁₅₅ share a pair of data strobe wirings DQSTL and DQSBL, the load on the memory controller side during write is reduced, resulting in an improved quality of the data strobe signal.

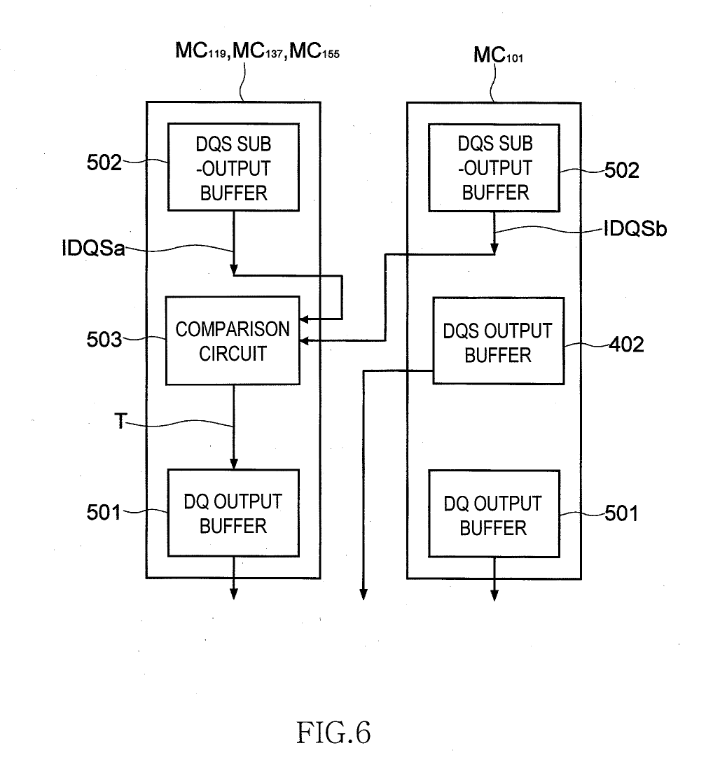

FIG. 6 is a block diagram showing data input/output circuits provided in the memory chips MC₁₀₁, MC₁₁₉, MC₁₃₇, and MC₁₅₅ shown in FIG. 1 and represents the fifth embodiment.

As shown in FIG. 6, these memory chips include data output circuits 501. The data output circuit 501 outputs read data via the data input/output terminal DQ. Read data output circuit parts of the respective memory chips have the same configuration.

On the other hand, regarding the data-strobe-signal output circuit, the memory chip MC₁₀₁ is provided with the DQS output buffer 402 with an ordinary driving capability. Meanwhile, the memory chips MC₁₁₉, MC₁₃₇, and MC₁₅₅ do not include the DQS output buffer with an ordinary driving capability but include a DQS sub-output buffer 502 with significantly reduced driving capability. The DQS output buffer 402 provided in the memory chip MC₁₀₁ is a circuit corresponding to the O buffer shown in FIG. 5 and outputs representatively the data strobe signal when the memory chips MC₁₀₁, MC₁₁₉, MC₁₃₇, and MC₁₅₅ perform the read operation. As in the example of FIG. 5, only the memory chip MC₁₀₁ outputs an effective data strobe signal during the read operation. Accordingly, a phase of the data strobe signal outputted by the memory chip MC₁₀₁ may be shifted slightly from the phase of read data outputted by the memory chips MC₁₁₉, MC₁₃₇, and MC₁₅₅.

Considering such shifting, the fifth embodiment provides the DQS sub-output buffer 502 in the memory chips MC₁₀₁, MC₁₁₉, MC₁₃₇, and MC₁₅₅. Further, a comparison circuit 503 is provided in the memory chips MC₁₁₉, MC₁₃₇, and MC₁₅₅ that do not include the data-strobe-signal output circuit 402.

The DQS sub-output buffer 502 is a circuit for generating a strobe signal IDQSa or IDQSb with reduced driving capability whose phase is controlled with respect to read data. The comparison circuit 503 compares the phase of the strobe signal IDQSa generated by the DQS sub-output buffer 502 within the memory chips MC₁₁₉, MC₁₃₇, and MC₁₅₅ to the phase of the strobe signal IDQSb generated by the DQS sub-output buffer 502 within the memory chip MC₁₀₁ to generate a timing adjusting signal T based on the result. The timing adjusting signal T is supplied to the data output circuit 501. The data output circuit 501 adjusts the timing of outputting read data based on the signal T.

Accordingly, although the memory chips MC₁₁₉, MC₁₃₇, and MC₁₅₅ do not output the effective data strobe signal, the phase of the data strobe signal outputted by the memory chip MC₁₀₁ can be made to coincide precisely with the phase of the read data outputted by the memory chips MC₁₁₉, MC₁₃₇, and MC₁₅₅.

As described above, while the DQS output buffer 402 is completely removed from the memory chips MC₁₁₉, MC₁₃₇, and MC₁₅₅ in the fourth embodiment, the DQS sub-output buffer 502 with significantly small driving capability can be provided in the memory chips MC₁₁₉, MC₁₃₇, and MC₁₅₅ as in the fifth embodiment.

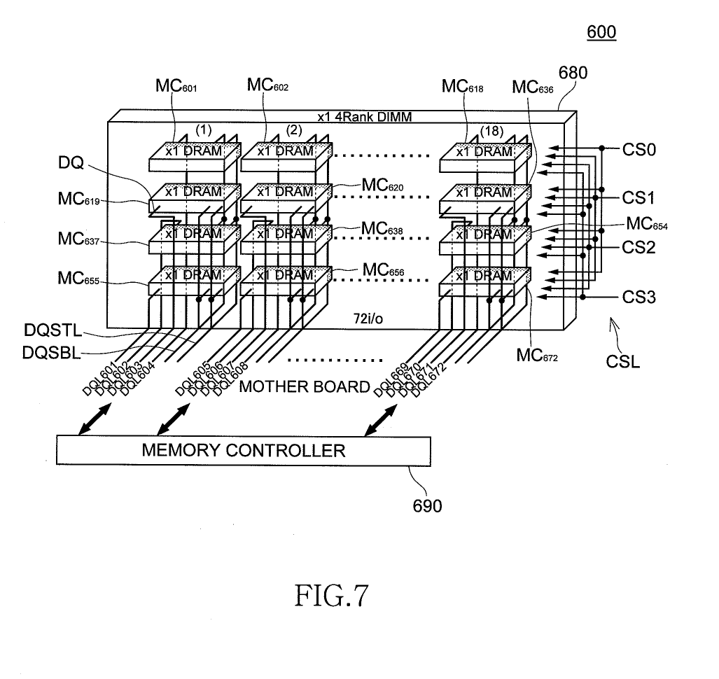

FIG. 7 is a schematic diagram of a configuration of a memory module 600 according to the sixth embodiment.

As shown in FIG. 7, the memory module 600 according to the sixth embodiment is different from the memory module 200 according to the second embodiment in that a half of the memory chips MC₆₀₁ to MC₆₁₈ and MC₆₃₇ to MC₆₅₄ are mounted on one surface of the module substrate 680 and the remaining half of the memory chips MC₆₁₉ to MC₆₃₆ and MC₆₅₅ to MC₆₇₂ are mounted on the other surface of the module substrate 680. Data signals transferred between the memory chips MC₆₀₁ to MC₆₁₈ and MC₆₃₇ to MC₆₅₄ are passed through the data input/output wirings (data lines) formed on one surface of the module substrate 680 and the mother board (main board). Similarly, data signals transferred between the memory chips MC₆₁₉ to MC₆₃₆ and MC₆₅₅ to MC₆₇₂ are passed through the data input/output wirings (data lines) formed on the other surface of the module substrate 680 and the mother board (main board).

For example, the memory chip MC₆₀₁ is electrically connected to the data input/output wiring DQL604 without connected to the data input/output wiring DQL603; and the memory chip MC₆₁₉ is electrically connected to the data input/output wiring DQL603 without connected to the data input/output wiring DQL604.

This configuration has an advantage in that an area of the module substrate 680 can be effectively used because the memory chips are mounted on both surfaces. The data strobe wirings DQSTL and DQSBL and chip select lines CSL connected between the memory chips MC₆₀₁ to MC₆₇₂ and memory controller 690 on which the data strobe signals DQS and the chip select signals CS0 to CS3 are transferred, respectively are also provided on both surface of the module substrate 680. The data strobe wirings DQSTL and DQSBL and chip select lines CSL are also provided on the mother board. The data strobe wirings DQSTL and DQSBL are connected in common to respective memory chips. For example, the memory chips MC₆₀₁, MC₆₁₉, MC₆₃₇ and MC₆₅₅ are connected to the same data strobe wirings DQSTL and DQSBL. The chip select lines CSL are connected in common to all the memory chips.

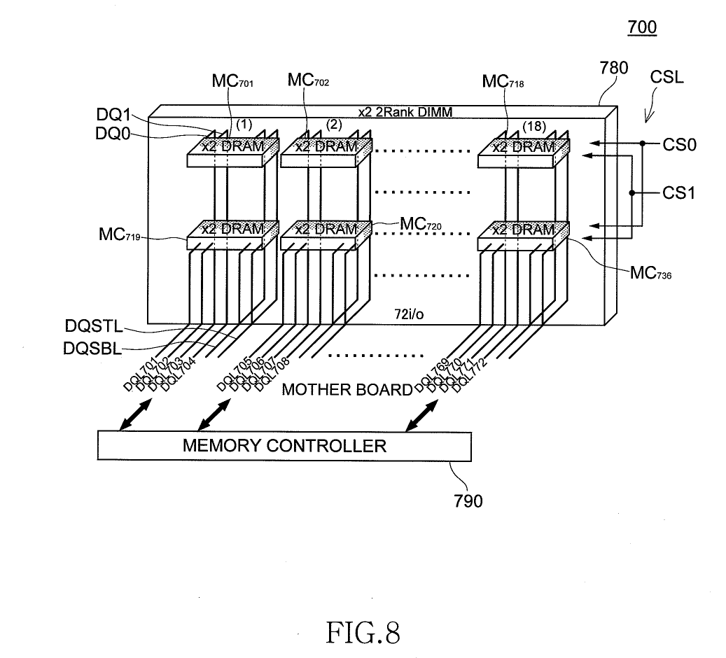

FIG. 8 is a schematic diagram of a configuration of a memory module 700 according to the seventh embodiment.

As shown in FIG. 8, the memory module 700 according to the seventh embodiment is different from the memory module 300 according to the third embodiment in that a half of the memory chips MC₇₀₁ to MC₇₁₈ are mounted on one surface of the module substrate 780 and the remaining half of the memory chips MC₇₁₉ to MC₇₃₆ are mounted on the other surface of the module substrate 780. According to this configuration an area of the module substrate 780 can be effectively used.

In this embodiment, the memory chip MC₇₀₁ mounted on one surface of the module substrate 780 is electrically connected to the data input/output wirings DQL703 and DQL704 without connected to the data input/output wiring DQL701 and 702; and the memory chip MC₇₁₉ mounted on the other surface of the module substrate 780 is electrically connected to the data input/output wirings DQL701 and DQL702 without connected to the data input/output wiring DQL703 and 704.

It is apparent that the present invention is not limited to the above embodiments, but may be modified and changed without departing from the scope and spirit of the invention.

For example, while the data strobe wiring is connected commonly to a plurality of memory chips in the above embodiments, this feature is not essential in the present invention. Therefore, the data strobe wiring can be connected to each of the memory chips.

While the read data and the write data are single end signals and the data strobe signal is a differential signal in the above embodiments, the present invention is not limited thereto. Therefore, for example, the read data and the write data can be differential signals. In this case, two data input/output wirings are required per bit.

Furthermore, the type of memory chips used in the present invention is not limited and apart from a DRAM, other types of memories such as a PRAM or a RRAM can be used.

While the number of memory chips connected to the same data strobe wiring is equal to the number of areas included in each memory chip in the second embodiment shown in FIG. 2 and the third embodiment shown in FIG. 4, this feature is not essential in the present invention.

What is claimed is:

1. A memory module comprising:
a module substrate;
a plurality of memory chips mounted on the module substrate, each of which includes a data input/output terminal; and
a plurality of data input/output wirings formed on the module substrate to which read data or write data is transmitted, each of the data input/output wirings being individually connected to an associated one of the data input/output terminal.

2. The memory module as claimed in claim 1, wherein a number of the memory chips is equal to a number of bits of the read data or the write data to be transmitted concurrently through the data input/output wirings.

3. The memory module as claimed in claim 2, wherein the number of the memory chips is equal to the number of the data input/output wirings.

4. The memory module as claimed in claim 1, wherein each of the memory chips is divided into a plurality of areas activated exclusively based on a plurality of chip select signals.

5. The memory module as claimed in claim 4, wherein the chip select signals are supplied commonly to the memory chips.

6. The memory module as claimed in claim 4, further comprising a data strobe wiring connected commonly to the memory chips, to which a data strobe signal indicating a timing of inputting/outputting the read data or the write data for the memory chips is transmitted.

7. The memory module as claimed in claim 6, wherein each of the memory chips including:
a data strobe terminal; and
a data-strobe-signal input circuit for receiving the data strobe signal via the data strobe terminal, wherein
a capacity of the data strobe terminal in terms of the data strobe wiring is relatively large in a predetermined memory chip among the memory chips and relatively small in other memory chips different from the predetermined memory chip.

8. The memory module as claimed in claim 7, wherein
the predetermined memory chip includes a data-strobe-signal output circuit for outputting the data strobe signal via the data strobe terminal, and
the other memory chips which are different from the predetermined memory chip do not include the data-strobe-signal output circuit.

9. The memory module as claimed in claim 7, wherein
each of the memory chips includes a data-strobe-signal output circuit for outputting the data strobe signal via the data strobe terminal, and
a driving capability of the data-strobe-signal output circuit provided in the predetermined memory chip is larger than that of the data-strobe-signal output circuit provided in the other memory chips different from the predetermined memory chip.

10. The memory module as claimed in claim 9, wherein
each of the memory chips further includes a data output circuit for outputting the read data via the data input/output terminal,
each of the other memory chips different from the predetermined memory chip includes a comparison circuit for comparing a phase of the data strobe signal generated by the data-strobe-signal output circuit provided therein to a phase of the data strobe signal generated by the data-strobe-signal output circuit provided in the predetermined memory chip to generate a timing adjusting signal, and
each of the data output circuits provided in the other memory chips different from the predetermined memory chip adjusts a timing of outputting the read data based on the timing adjusting signal.

11. A memory module comprising:
a module substrate;
a plurality of memory chips mounted on the module substrate;
a plurality of data input/output wirings formed on the module substrate to which read data or write data is transmitted, each of the data input/output wirings being individually connected to an associated one of the memory chips; and
a data strobe wiring formed on the module substrate to which a data strobe signal indicating a timing of inputting/outputting the read data or the write data for the memory chips is transmitted, each of the data strobe wiring being connected commonly to the memory chips.

12. A system comprising:
a main board;
a controller provided on the main board;
a memory module provided on the main board, the memory module including a module board which comprises first and second surfaces opposed to each other and first and second memory chips mounted on the first and second surfaces of the module board, respectively; and
first and second data wirings provided on the main board, the first and second data wirings connecting the controller with the memory module;
wherein the first memory chip is electrically connected to the first data line and electrically disconnected from the second data line, the second memory chip is electrically connected to the second data line and electrically disconnected from the first data line.

13. The system as claimed in claim 12, further comprising third and fourth data wirings provided between the controller and the memory module on the main board, the first memory chip being electrically connected to the third data line and electrically disconnected from the fourth data line, and the second memory chip being electrically connected to the fourth data line and electrically disconnected from the third data line.

14. The system as claimed in claim 12, further comprising a chip select line, on which the controller supplies a chip select signal, provided between the controller and the memory module on the main board, and each of the first and second chips being electrically connected to the chip select line.

15. The system as claimed in claim 12, further comprising a data strobe line, on which the controller supplies a data strobe signal, provided between the controller and the module on the main board, and each of the first and second chips being electrically connected to the data strobe line.
